(19) United States
(12) Patent Application Publication
(10) Pub. No.: US 2026/0216920 A1
(43) Pub. Date: Jul. 30, 2026

(54) METHOD FOR PRODUCING AN OPTICAL SYSTEM FOR A LITHOGRAPHY APPARATUS, SUBSTRATE FOR AN OPTICAL COMPONENT OF A LITHOGRAPHY APPARATUS, AND LITHOGRAPHY APPARATUS

(71) Applicant: Carl Zeiss SMT GmbH, Oberkochen (DE)

(72) Inventors: Norman BAER, Aalen (DE); Matthias DREHER, Oberkochen (DE); Matthias EXLER, Aalen (DE); Florian JAKOBS, Heidenheim an der Brenz (DE); Ulrich LOERING, Ulm (DE); Antonio NEGRETTI, Hamburg (DE); Henrik RONELLENFITSCH, Aalen (DE); Malte LANGENHORST, Aalen (DE)

(21) Appl. No.: 19/629,370

(22) Filed: Mar. 26, 2026

Related U.S. Application Data
(63) Continuation of application No. PCT/EP2024/076339, filed on Sep. 19, 2024.

(30) Foreign Application Priority Data
Sep. 27, 2023 (DE) 10 2023 209 473.8
Dec. 14, 2023 (DE) 10 2023 212 752.0

(51) Int. Cl. B28D 7/00; B28D 1/22; G02B 5/08; G03F 7/00

(52) U.S. Cl. CPC B28D 7/005; B28D 1/22; G03F 7/706; G03F 7/70891; G03F 7/70975; G02B 5/0891

(57) ABSTRACT

Optical system production method includes (a) providing (S2) a distribution function (g) for a zero-crossing temperature (ZCT_{R}) of a coefficient of thermal expansion (α_{R}) of the raw block as a function of a location (p) of the raw block, (b) ascertaining (S3), an aberration (Fᵢ) of the optical system, for the provided distribution function and each of a plurality of positions (Pᵢ) of a cutout region (D) of the raw block that differ from one another with respect a radial position (rᵢ) and/or a height position (hᵢ) of the raw block, and (c) ascertaining (S4) at least one selection position (Pₐ) of the cutout region (D) as the position (Pᵢ) for which the ascertained aberration (Fᵢ) is less than a predetermined threshold value (SW).

### CROSS REFERENCE TO RELATED APPLICATIONS

This is a Continuation of International Application PCT/EP2024/076339, which has an international filing date of Sep. 19, 2024, and which claims the priority of German Patent Application 10 2023 209 473.8, filed Sep. 27, 2023, and German Patent Application 10 2023 212 752.0, filed Dec. 14, 2023. The disclosures of each of these applications are incorporated in their respective entireties into the present Continuation by reference.

### FIELD

The present invention relates to a method for producing an optical system for a lithography apparatus, to a substrate for an optical component of the optical system of the lithography apparatus and to a lithography apparatus having such a substrate.

### BACKGROUND

Microlithography is used to produce microstructured component parts, for example integrated circuits. The microlithography process is carried out using a lithography apparatus comprising an illumination system and a projection system. The image of a mask (reticle) illuminated with the illumination system is projected here by the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, extreme ultraviolet (EUV) lithography apparatuses that use light with a wavelength in the range from 0.1 nm to 30 nm, in particular 13.5 nm, are currently under development. Since most materials absorb light of this wavelength, it is necessary in such EUV lithography apparatuses to use reflective optics, i.e. mirrors, instead of—as previously—refractive optics, i.e. lens elements.

A problem that arises in the process is that the mirrors heat up as a consequence of absorbing the radiation emitted by the EUV light source. This can lead to a thermal deformation of the mirrors. Furthermore, an optical coating of the mirrors might also degrade as a result of an increase in temperature. Both thermal deformations of the mirrors and damage to their optical coatings may adversely affect the imaging properties of the mirrors.

The imaging quality of a projection system of an EUV lithography apparatus depends greatly on the quality of the mirror material. A material with a very small coefficient of thermal expansion is used for the mirror substrates in order to reduce aberrations due to the mirrors heating. In particular, a deformation of the mirror material as a function of a temperature increase is minimal and/or zero at the so-called zero-crossing temperature of the coefficient of thermal expansion of the mirror material. The mean zero-crossing temperature of the mirror material and variations of the zero-crossing temperature within the mirror substrate volume have a direct influence on aberrations caused by mirror heating.

### SUMMARY

Against this background, one object addressed by the present invention is that of providing an improved method for producing an optical system for a lithography apparatus and an improved substrate for an optical component of an optical system of the lithography apparatus.

According to a first aspect, a method for producing an optical system for a lithography apparatus is proposed. The optical system comprises an optical component having a substrate which is cut out of a raw block. Furthermore, the method comprises the following steps:
a) providing a distribution function for a zero-crossing temperature of a coefficient of thermal expansion of the raw block as a function of a location of the raw block, the distribution function being rotationally symmetric with respect to an axis of symmetry of the raw block,
b) ascertaining, in computer-implemented fashion, an aberration of the optical system, for the provided distribution function and each of a plurality of positions of a cutout region of the raw block that differ from one another, with the plurality of positions of the cutout region differing from one another in relation to a radial position and/or a height position of the raw block, and
c) ascertaining at least one selection position of the cutout region as the position from the plurality of positions for which the ascertained aberration is less than a predetermined threshold value.

The method allows a region corresponding to the ascertained cutout region to be cut out of the blank and a substrate of an optical component to be produced therefrom. In particular, the method is used to ascertain a cutout region of the raw block which has an advantageous distribution of the zero-crossing temperature. As a result, the method allows targeted setting of a distribution of the zero-crossing temperature within the substrate-within the scope of the distribution of the zero-crossing temperature provided by the raw block. Aberrations of the optical system on account of thermal expansion of the substrate can be reduced therewith.

A substrate material of an optical component usually has inhomogeneities which lead to an inhomogeneous distribution of the zero-crossing temperature over the substrate volume. This even applies to a high-performance substrate material. The inhomogeneous distribution of the zero-crossing temperature has an influence on the imaging properties of the optical component, and hence of the optical system with the optical component.

For a given distribution of the zero-crossing temperature over the volume of the raw block, the proposed method now allows ascertainment of an advantageous and/or optimal cutout region for the substrate of an optical component of a lithography apparatus. As a result, thermal deformations caused by heat inputs into the optical component (e.g. by irradiation with EUV light) and ensuing deteriorations in the imaging properties can be reduced or avoided.

The lithography apparatus can be a EUV lithography apparatus. EUV stands for “extreme ultraviolet” and denotes a wavelength of the operating light of between 0.1 nm and 30 nm. The lithography apparatus can also be a DUV lithography apparatus. DUV stands for “deep ultraviolet” and denotes a wavelength of the operating light of between 30 nm and 250 nm.

The optical device is for example a projection system of the lithography apparatus. However, in other examples, the optical system can also be an illumination system of the lithography apparatus (projection exposure apparatus).

The optical component of the optical system comprises an optically active surface and the substrate in particular.

For example, the optical component is a mirror, and the substrate is a mirror substrate. The optically active surface is a reflective surface in this case in particular.

In particular, the substrate is cut out of the raw block as one piece (in one piece).

The coefficient of thermal expansion specifies a change in the geometric shape and the dimensions of a material in the case of a temperature change. For example, the coefficient of thermal expansion is a linear coefficient of thermal expansion, which specifies a change in material length as a function of a change in temperature.

The material of the raw block (and hence of the substrate to be produced from the raw block) is a material with a very low coefficient of thermal expansion in particular. For example, the coefficient of thermal expansion is within a range of +/−20 ppb/K (parts per billion per Kelvin), +/−15 ppb/K, +/−10 ppb/K and/or +/−5 ppb/K at a desired operating temperature. However, the coefficient of thermal expansion can also be within a different range. In such a material with very little thermal expansion, changes in the geometric shape and in the dimensions on account of temperature changes occur to only a very small degree.

Examples of the material of the raw block (and hence of the substrate to be produced from the raw block) comprise quartz glass, titanium-doped quartz glass, and a glass ceramic. For example, the raw block material is a material with an ultra-low thermal expansion (e.g. a substrate material sold by Corning Inc. under the trademark “ULE”, which stands for “ultra-low expansion”). For example, the raw block material comprises a glass material made of TiO2-SiO2, in which the ultra-low coefficient of thermal expansion is realized by varying the concentration of TiO2. A further example is a Li2O—Al2O3-SiO2 glass ceramic (sold by Schott under the trademark “Zerodur”) with a crystalline phase, in which the ultra-low coefficient of thermal expansion is realized by uniformly distributed nanocrystals in a residual glass phase.

The coefficient of thermal expansion itself is temperature-dependent, i.e. a temperature-dependent function. The coefficient of thermal expansion can have a so-called zero-crossing temperature (ZCT). At the zero-crossing temperature, the coefficient of thermal expansion of a material has a zero crossing in its temperature dependence, in the proximity of which there is no thermal expansion, or only a negligible thermal expansion, of the material in the case of a change in temperature.

For example, the raw block is produced in a direct deposition process or in a soot process. For example, the raw block is produced by depositing glass material from one or more burners on a rotating blank. In the process, the material is constructed layer-by-layer while the extant raw block rotates quickly. This smears out inhomogeneities, and a rotationally symmetric distribution of the inhomogeneities forms as a result.

For example, the distribution function of the zero-crossing temperature of the raw block corresponds to a distribution function of a material composition of the raw block, for instance a titanium content or an OH content.

The distribution function of the zero-crossing temperature of the raw block specifies a value of the zero-crossing temperature, for example for each location of the raw block, i.e. for each volume element of the raw block.

In particular, the distribution function of the zero-crossing temperature is a three-dimensional distribution function.

The raw block has a rotationally symmetric distribution function of the zero-crossing temperature. In particular, the raw block has the axis of symmetry which is an axis of symmetry with respect to a rotation. In particular, the distribution function of the zero-crossing temperature of the raw block is mapped onto itself for rotations through any desired angle about the axis of symmetry. It could also be said that the distribution function has a rotationally symmetric pattern of the zero-crossing temperature with respect to the axis of symmetry of the raw block.

For example, the raw block itself is also rotationally symmetric, with the result that the raw block, as solid of revolution, is mapped onto itself for rotations through any desired angle about the axis of symmetry.

In particular, the raw block is a material blank for producing the substrate.

In particular, the cutout region is a three-dimensional cutout region of the raw block. For example, the cutout region is cuboid. However, the cutout region can have any other geometric shape. In embodiments, the same may apply to the one or more deviation cutout regions mentioned below.

Different positions of a cutout region are provided for the purpose of ascertaining the aberration of the optical system. It could also be said that different cutout regions are provided therewith, with the different cutout regions merely differing in terms of their position within the raw block. However, there is no difference in shape (e.g. geometric shape) and volume of the various cutout regions.

A radial position of the raw block is a radial position within the raw block in particular. A height position of the raw block is a height position within the raw block in particular.

For example, a respective position of the cutout region comprises a centre position (e.g. a centre and/or geometric centre) of the cutout region. In an alternative to that or in addition, a respective position of the cutout region can for example also comprise positions of outer boundaries, outer edges and/or an outer shape of the cutout region. In embodiments, the same may apply to the one or more deviation positions and assigned deviation cutout region(s) mentioned below. In this respect, the respective or corresponding position and deviation position, if applicable, of the cutout region and deviation cutout region, respectively, can be defined as a family of points or as a vector, or can comprise such a family of points or such a vector.

For example, the ascertainment of the respective aberration (and deviation aberration, if applicable) of the optical system on the basis of the various positions of the cutout region (and deviation positions of the deviation cutout region, if applicable) is performed with the aid of a computer-aided simulation. Furthermore, the distribution function of the zero-crossing temperature of the raw block provided in step a) and each of the plurality of provided positions of the cutout region (and deviation positions of the deviation cutout region, if applicable) of the raw block that differ from one another form input parameters of the simulation calculation. An aberration is ascertained for each combination of the provided distribution function of the zero-crossing temperature and the provided positions of the cutout region (and deviation positions of the deviation cutout region, if applicable). In particular, the ascertained aberrations (and deviation aberration, if applicable) form output parameters of the simulation calculation.

For example, step a) and/or step c) is/are also performed in computer-implemented fashion. For example, steps a), b) and/or c) are performed by a controller, for example a controller of one or more computers.

In embodiments, the predetermined threshold value is provided—especially in or before step c)—in a data memory of the controller or on a network (e.g. a cloud), in which or to which the controller is or can be connected in data-communicating fashion. Before the predetermined threshold value is provided, this value can be determined or calculated on the basis of one or more properties of the optical system, of the lithography apparatus and/or of the wafer to be produced by the lithography apparatus.

In embodiments, a plurality of selection positions of the cutout region (and of the deviation cutout region, if applicable), for example more than 1, 2, 5 or 10 selection positions, are ascertained in step c), wherein the aberration ascertained for each selection position is less than the predetermined threshold value.

Should more than one selection position of the cutout region for which the ascertained aberration is less than the predetermined threshold value be determined in step c), then a substrate can be cut out of the raw block in accordance with each of the plurality of ascertained selection positions.

Should no selection position of the cutout region for which the ascertained aberration is less than the predetermined threshold value be determined in step c), then it may for example be established that the raw block is not suitable for the production of a substrate.

For example, should the respective ascertained aberration (and deviation aberration, if applicable) comprise a focus error of the imaging process (i.e. a deviation of an actual focus of the optical system from a target focus), then the threshold value is for example 15 nm or less, 10 nm or less and/or 5 nm or less.

For example, should the respective ascertained aberration (and deviation aberration, if applicable) comprise an overlay error of the imaging process (i.e. a deviation of an actual position of an object imaged into an image in an image plane of the optical system with the aid of the optical system from a target position), then the threshold value is for example 3 nm or less, 1 nm or less and/or 0.5 nm or less.

For example, should the respective ascertained aberration (and deviation aberration, if applicable) comprise a spherical wavefront error of the imaging process (i.e. a deviation of an actual wavefront of a beam guided through the optical system from an ideal spherical wave), then the threshold value is for example 200 pm or less, 100 pm or less and/or 50 pm or less (RMS deviation).

In embodiments of the first aspect, even more than one distribution function of the zero-crossing temperature of the raw block can be applied as input parameters for ascertaining the respective aberration, wherein the plurality of distribution functions of the zero-crossing temperature of the raw block differ from one another by an offset of the mean zero-crossing temperature of the distribution function. In other words, it is possible to ascertain (e.g. measure) a distribution function of the zero-crossing temperature of the raw block which has a first mean zero-crossing temperature. Furthermore, one or more further distribution functions of the zero-crossing temperature of the raw block can be ascertained such that they emerge from the first distribution function of the zero-crossing temperature by the addition or subtraction of an offset from a mean zero-crossing temperature.

According to an embodiment of the first aspect, an optimal position of the cutout region is ascertained in step c) as the position from the plurality of positions for which the ascertained aberration is minimal.

The position of the cutout region can be ascertained even better therewith.

For example, a plurality of selection positions of the cutout region can be ascertained at first. Thereupon, the selection position from the plurality of selection positions for which the ascertained aberration is minimal can be ascertained as the optimal position.

According to a further embodiment of the first aspect, the cutout region is free from the axis of symmetry.

That is to say, the cutout region does not contain the axis of symmetry. In other words, outer edges of the cutout region do not intersect the axis of symmetry of the raw block. In particular, none of the outer edges of the cutout region intersect the axis of symmetry of the raw block.

As a result, the cutout region of the substrate of the optical component can avoid a region of the axis of symmetry of the raw block in which inhomogeneities (i.e. variations) of the zero-crossing temperature are particularly large.

What can also be achieved is that the substrate cut out in accordance with the ascertained cutout region has an advantageously patterned distribution function of the zero-crossing temperature of the coefficient of thermal expansion as a function of the location of the substrate. In particular, the pattern of the zero-crossing temperature of the substrate only comprises concentric ring sections (which are each partial sections of a complete ring)—but no complete rings. Furthermore, as seen from an outer edge of the substrate, the concentric ring sections have only concave curvatures or only convex curvatures.

The deviation cutout regions mentioned hereinafter can also be free from the axis of symmetry.

According to a further embodiment of the first aspect, the raw block has a cylindrical shape with a cylinder axis corresponding to the axis of symmetry and a lateral surface. Moreover, the radial position of the raw block is a position along a radial direction of the raw block, with the radial direction extending from a radius equal to zero at the axis of symmetry to an outer radius (of greater than zero) at the lateral surface.

In particular, the cylindrical shape has two opposite end faces (bases), which are connected to one another by the lateral surface. For example, the two opposite end faces are arranged parallel to one another.

In particular, the shape of the cylinder is the shape of a right circular cylinder. In that case, the two opposite end faces are circular surfaces in each case.

According to a further embodiment of the first aspect, the plurality of positions of the cutout region each have a radius of greater than zero.

This means that the cutout region does not contain the axis of symmetry, where the radius of the raw block equals zero.

For example, the entire cutout region (i.e. including the positions of all its outer edges) has a radius of greater than zero.

The deviation positions of the deviation cutout region mentioned hereinafter can also have a radius greater than zero in each case.

According to a further embodiment of the first aspect:
the plurality of positions of the cutout region cover a radial range of the raw block from an inner radius adjacent to the axis of symmetry to an outer radius at a lateral surface of the raw block, and/or
the plurality of positions of the cutout region cover a height range of the raw block from a first end face to a second end face of the raw block.

Consequently, the ascertainment of the aberration of the optical system gives consideration to positions of the cutout region which cover the entire radius of the blank with the exception of the axis of symmetry itself, where the radius equals zero, and/or which cover the entire height of the blank.

According to a further embodiment of the first aspect:
the raw block has a first, second and third direction,
the third direction is arranged along the axis of symmetry of the raw block,
the first and second direction are arranged perpendicular to one another and in each case perpendicular to the axis of symmetry, and
the plurality of positions of the cutout region differ from one another in relation to the radial position and/or the height position of the raw block and in relation to a rotation about the first, second and/or third direction.

As a result, it is also possible to give consideration to one or more rotational degrees of freedom in relation to the first, second and/or third direction of the raw block for the purpose of ascertaining the optimal cutout region (i.e. the optimal position of the cutout region).

For certain use cases, the applicant has established that aberrations of the optical system can be reduced by up to 30 to 40% using the substrate produced thus.

The first and second direction are arranged parallel with a radial direction of the raw block in each case, with an azimuth angle between the first and the second direction being 90 degrees. In particular, the third direction coincides with the axis of symmetry.

According to a further embodiment of the first aspect:
one or more deviation aberrations from one or more deviation positions of the cutout region are also ascertained for each of the plurality of positions of the cutout region that differ from one another, in addition to the aberration for the corresponding position of the corresponding cutout region,
the one or more deviation positions are chosen such that one or more deviation cutout regions defined thereby are located within a tolerance region around the corresponding cutout region defined by the corresponding position, and
the at least one selection position of the cutout region is ascertained as the position from the plurality of positions for which the ascertained aberration and the one or more ascertained deviation aberrations are each less than the predetermined threshold value.

By ascertaining and considering the aberrations not only for a specific position of the cutout region but, additionally, for one or more deviation positions associated with the specific position, it is possible to take account of imprecisions during the subsequent cutout of the substrate (e.g. on account of tolerances of the cutting tool) according to the ascertained selection position and/or the ascertained optimal position.

For example, the respective tolerance region comprises the corresponding cutout region.

For example, the respective tolerance region is larger than the corresponding associated cutout region by 0.01% or more, by 0.1% or more, by 1% or more and/or by 3% or more. In addition to that or instead, the respective tolerance region can for example also be larger than the corresponding associated cutout region by 1 mm or more, 5 mm or more and/or 10 mm or more (e.g. in each spatial direction).

For example, the respective tolerance region has the same geometric shape as the corresponding associated cutout region and has only been enlarged true to scale in comparison with the corresponding associated cutout region. In particular, the respective tolerance region and the corresponding associated cutout region have the same centre position (e.g. the same centre and/or the same geometric centre).

According to a further embodiment of the first aspect:
the raw block has a first, second and third direction,
the third direction is arranged along the axis of symmetry of the raw block,
the first and second direction are arranged perpendicular to one another and in each case perpendicular to the axis of symmetry, and
the one or more deviation positions differ from the corresponding position of the corresponding cutout region in relation to:
   the radial position,
   the height position,
   a displacement in the first, second and/or third direction,
   a rotation about the first, second and/or third direction,
   non-parallel edges of the deviation cutout region, in each case in the first, second and/or third direction, and/or
   a volume deviation of the one or more deviation cutout regions from the corresponding cutout region defined by the corresponding position.

According to a further embodiment of the first aspect, an error range of the ascertained aberration is additionally ascertained during the computer-implemented ascertainment of the respective aberration of the optical system, and the at least one selection position of the cutout region is ascertained as the position from the plurality of positions for which the ascertained aberration including its error range is less than the predetermined threshold value.

By taking account of the error range of the aberration, the selection position of the cutout region can be ascertained even better. In particular, it is possible to ensure that, even at the limits of its margins of error, the ascertained aberration is less than the predetermined threshold value.

According to a further embodiment of the first aspect, the respective aberration is ascertained with the aid of a computer-based simulation, and the error range of the ascertained aberration is ascertained on the basis of one or more error ranges of one or more input parameters of the simulation.

This allows consideration to be given to the fact that input parameters of the simulation might be afflicted by errors.

According to a further embodiment of the first aspect, the error range of the ascertained aberration is ascertained on the basis of an error range of the provided distribution function for the zero-crossing temperature.

For example, the error range of the provided distribution function for the zero-crossing temperature comprises margins of error for the zero-crossing temperature at each location of the raw block. For example, the error range of the provided distribution function for the zero-crossing temperature might also comprise a deviation of the distribution function of the zero-crossing temperature from a rotationally symmetric distribution function.

According to a further embodiment of the first aspect, the respective aberration is ascertained with the aid of a computer-based simulation, and the error range of the ascertained aberration is ascertained on the basis of giving consideration to one or more systematic errors of the simulation.

For example, systematic errors of the simulation comprise errors on account of an interpolation of data processed during the simulation calculation. For example, systematic errors of the simulation might also comprise deviations that arise due to the choice of calculation rules for the simulation.

According to a further embodiment of the first aspect, the ascertainment of the respective aberration of the optical system includes:
ascertaining a plurality of individual errors that differ from one another, in relation to error types of the optical system that differ from one another, and ascertaining the respective aberration of the optical system on the basis of the plurality of ascertained individual errors.
The embodiments and features of the ascertainment of the respective aberration on the basis of the plurality of ascertained individual errors, as described herein, can also apply to the ascertainment of respective deviation aberrations, where applicable.

For example, a plurality of relative individual errors that differ from one another are ascertained in relation to the error types of the optical system that differ from one another. Furthermore, the respective aberration (and deviation aberration, if applicable) of the optical system is for example ascertained as a maximum, a mean value, a median and/or a quantile of the plurality of ascertained relative individual errors.

For example, the at least one selection position of the cutout region can also be ascertained in step c) as the position from the plurality of positions for which each of the plurality of ascertained individual errors is less than a corresponding predetermined individual threshold value for the corresponding error type.

In particular, the plurality of individual errors that differ from one another have error values for different types of individual errors.

By giving consideration to different types of individual errors of the imaging process of the optical system, the final error of the imaging process of the optical system can be ascertained even better for the provided distribution function and each provided position of the cutout region.

Moreover, the maximum, the mean value, the median and/or the quantile of the plurality of ascertained individual errors, for example, is calculated—for the provided distribution function and each considered position of the cutout region—and the final error of the imaging process of the optical system is subsequently taken to be this maximum, this mean value, this median and/or this quantile. This allows better consideration to be given to large error contributions.

In embodiments, the plurality of ascertained individual errors are weighted in accordance with predetermined weights. As a result, the individual errors can be weighted depending on a planned use of the optical component to be produced and of the optical system having this component. This allows error contributions to performance parameters that are particularly important to a specific application of the optical component/optical system to be kept small in a targeted manner.

According to a further embodiment of the first aspect, the plurality of individual errors that differ from one another are ascertained in relation to the error types that differ from one another and in relation to setting parameters of an illumination of the optical component, to be produced, of the optical system with operating light that differ from one another.

As a result, different setting parameters of the planned illumination of the optical component, to be produced, with operating light (e.g. EUV light) are taken into account during the computer-implemented ascertainment of the individual errors. Consequently, the various types of individual error can be ascertained for different simulated illumination scenarios for the optical component to be produced.

For example, the various setting parameters of the planned illumination of the optical component to be produced comprise a radiation intensity of the operating light (e.g. EUV light), which is radiated onto the optical component.

For example, the various setting parameters of the illumination can also comprise a pattern, with which the operating light is radiated onto the optical component (e.g. X-dipole, Y-dipole, ring shape, circular shape, DRAM profile, stripe pattern, irregular pattern, etc.). In other words, the illumination setting parameters may comprise a heat flux distribution with heat flux poles which is caused by operating light radiated in a specific pattern onto the optical component to be produced.

For example, the various setting parameters for the illumination may also comprise a structure of a mask (e.g. lithography mask), which is imaged with the aid of the optical component to be produced onto a wafer in the image plane of the optical system.

According to a further embodiment of the first aspect, the plurality of individual errors that differ from one another are ascertained in relation to setting parameters of a heating of the optical component, to be produced, by an external heating device that differ from one another.

As a result, different setting parameters of the planned heating of the optical component, to be produced, by the external heating device are taken into account during the computer-implemented ascertainment of the individual errors. Consequently, the individual errors can be ascertained for different simulated heating scenarios for the optical component to be produced.

For example, the various setting parameters for the planned heating of the optical component to be produced comprise a predicted heat input into the optical component by the heating, a predetermined temperature, to which the optical component to be produced should be heated, and/or a heating pattern applied during the planned heating. For example, the heating pattern is a temperature pattern that should be realized in the optical component. For example, the heating pattern is a two-dimensional or three-dimensional spatially dependent target temperature map of the optical component.

For example, the planned heating of the optical component to be produced serves to correct one or more error types of an imaging process. For example, the planned heating of the optical component to be produced creates a local compression and/or expansion of a material of the optical component, in order to deform the optical component such that a specific wavefront error can be compensated.

How well an aberration according to the corresponding error type can be corrected by heating with the external heating source depends inter alia on the distribution of the zero-crossing temperature of the substrate of the optical component. For example, it is advantageous for a correction of aberrations through heating if a cutout region of the raw block from which the substrate is manufactured has a zero-crossing temperature distribution that is symmetric (to the best possible extent) with respect to an axis of symmetry of a heating pattern that is applied during the planned heating of the optical component to be produced. Moreover, both the compression temperature domain (i.e. the temperature range in which a material is compressed on account of the temperature applied) and the expansion temperature domain (i.e. the temperature range in which a material is expanded on account of the temperature applied) of the optical component to be produced depend on the zero-crossing temperature in the regions of the optical component to be compressed and expanded, respectively. In other words, the compression temperature domain and the expansion temperature domain of the optical component to be produced depend on the spatial distribution of the zero-crossing temperature of the substrate of the optical component to be produced.

For example, the external heating device is configured to heat an optically active surface and/or a substrate of the optical component to be produced.

For example, the external heating device is configured to heat the optical component to be produced (e.g. its substrate and/or its optically active surface) on a sector-specific basis. That is to say, the optical component to be produced is not heated uniformly to the same temperature, but individual regions (i.e. sectors) of the optical component to be produced are heated to temperatures (according to a heating pattern) that differ from one another. For example, one or more regions of the optical component to be produced are heated to a temperature that brings about a local compression of a material of the optical component to be produced (e.g. of its substrate). Furthermore, one or more regions of the optical component to be produced are for example heated to a temperature that brings about a local expansion of a material of the optical component to be produced (e.g. of its substrate). In particular, local compressions and expansions of the substrate material can be created on account of the non-linear behaviour of the substrate material due to heating. Therefore, whether a specific region (sector) is compressed or expanded by the external heating can be set by choosing the temperature for this region. Aberrations can be corrected thereby in a targeted manner.

For example, the external heating device comprises radiant heaters (e.g. infrared heaters) configured to radiate heating radiation (e.g. infrared radiation) onto the optical component to be produced. However, the heating device can also be configured to heat the optical component by thermal conduction-rather than heating radiation (i.e. thermal radiation).

According to a further embodiment of the first aspect, heating of the optical component, to be produced, by the external heating device includes heating in accordance with a heating pattern or a plurality of different heating patterns, which is/are adapted accordingly for correcting one or more of the various error types. Moreover, the plurality of individual errors that differ from one another are ascertained in relation to the one heating pattern or the plurality of heating patterns that differ from one another.

Hence, a heat input into the optical component, to be produced, in accordance with the heating pattern or the various heating patterns of the planned heating can be taken into account during the computer-implemented ascertainment of the individual errors. Hence, the computer-implemented ascertainment of the individual errors can also give consideration as to how well (e.g. up to what degree) a corresponding error type can be corrected by the planned heating. Consequently, the correction of one or more different error types by planned heating and the quality of this correction, which depends on the distribution of the zero-crossing temperature of the substrate of the optical component, can be taken into account during the computer-implemented calculation of the individual errors.

According to a further embodiment of the first aspect, the plurality of ascertained individual errors comprise the following in relation to the error types that differ from one another:
a deviation of an actual focus of the optical system from a target focus,
a deviation of an actual position of an object imaged in an image plane of the optical system with the aid of the optical system from a target position of the imaged object,
an image displacement of an image imaged in an image plane of the optical system with the aid of the optical system, and/or
a deviation of an actual wavefront, which images an image in an image plane of the optical system, from a target wavefront.

The individual errors are ascertained in computer-implemented fashion in particular, for example on the basis of a simulation of an imaging process using the optical system to be produced.

For example, the image displacement is a displacement of the image relative to a target position of the image. For example, the image displacement is a displacement of the image in a direction parallel to the image plane of the optical system.

The image imaged in an image plane of the optical system is for example an image imaged on a wafer of the lithography apparatus.

The actual wavefront is the wavefront of a beam guided through the optical system in particular. For example, the actual wavefront is the wavefront of the beam at the location of the image plane.

For example, the target wavefront is a spherical wave. The deviation of the actual wavefront from the target wavefront is for example a deviation from an ideal spherical wave.

According to a further embodiment of the first aspect:
the deviation of the actual wavefront from the target wavefront comprises a tilt of the wavefront, a displacement of the wavefront, an astigmatism of the wavefront, a coma of the wavefront, a higher-order (n)-foil aberration of the wavefront and/or a spherical aberration of the wavefront, and/or
the deviation of the actual wavefront from the target wavefront is quantified in the form of Zernike polynomials.

For example, the tilt of the wavefront is a tilt about an axis (e.g. x- and/or y-axis) which is arranged parallel to the image plane of the optical system.

For example, the displacement of the wavefront is a displacement parallel to the image plane of the optical system (e.g. in the x- and/or y-direction).

The higher-order (n)-foil aberration is e.g. a trefoil aberration, a quadrafoil aberration, pentafoil aberration, hexafoil aberration, etc., of the wavefront.

With the aid of Zernike polynomials, it is possible to mathematically represent a deviation of a real wavefront from an ideal wavefront through a sum of polynomials. Zernike polynomials are represented with the aid of polar coordinates in a normalized unit circle. Mathematically, the individual Zernike polynomials of a circular area are characterized by polar coordinates with a power series in the radial direction ρ and a Fourier-like series in the direction of the angle Θ. In the general form Z n,±m, n specifies the order of the polynomial in the radial direction, and m corresponds to the frequency of the angle Θ per revolution. Polynomials with even n and m=0 are rotationally symmetric, and all others are angle dependent.

For example, the Zernike polynomial Z 1,±1 describes a tilt (+1 in the x-direction, −1 in the y direction), the Zernike polynomial Z 2,0 describes a defocus (spherical error), the Zernike polynomial Z 2,±2 describes an astigmatism, the Zernike polynomial Z 3,±1 describes a coma, the Zernike polynomial Z 3,±3 describes a trefoil aberration, the Zernike polynomial Z 4,0 describes a spherical aberration and the Zernike polynomial Z 4,±2 describes a 4th order astigmatism.

According to a further embodiment of the first aspect, the method includes the following steps:
providing the raw block, and
measuring the distribution function of the zero-crossing temperature of the raw block.

The distribution function of the zero-crossing temperature is measured in particular for the entire volume, i.e. all positions, of the raw block.

An error range of the distribution function of the zero-crossing temperature can also be ascertained when measuring the distribution function of the zero-crossing temperature of the raw block.

According to a further embodiment of the first aspect, the method includes the following steps:
providing the raw block, and
cutting out the substrate from the raw block according to the at least one ascertained selection position of the cutout region and/or the ascertained optimal position of the cutout region.

In particular, the raw block is provided physically. Moreover, the raw block is provided in particular before step a).

In particular, the substrate is cut out of the raw block as one piece (i.e. in one piece).

According to a second aspect, a substrate for an optical component of an optical system of a lithography apparatus is proposed. The substrate comprises a distribution function of a zero-crossing temperature of a coefficient of thermal expansion as a function of a location of the substrate. Moreover, the distribution function comprises a pattern of the zero-crossing temperature which comprises a plurality of concentric ring sections, which are partial sections of a complete ring in each case.

The respective complete rings are circular rings in particular.

According to an embodiment of the second aspect:
an auxiliary line of the substrate is defined such that it is arranged perpendicular to mutually parallel tangents at the ring sections and runs through an imaginary centre of the imaginary complete rings that correspond to the ring sections, and
the auxiliary line is arranged parallel to a longitudinal direction of the substrate, or
the auxiliary line is arranged at an angle to the longitudinal direction of the substrate.

According to a third aspect, a lithography apparatus is proposed. The lithography apparatus comprises a substrate as described above and/or an optical system having an optical component with a substrate as described above.

According to a further aspect, a computer program product is proposed, comprising instructions that, upon execution of the program by at least one computer, cause the computer to carry out the above-described method (e.g. one or more embodiments of the above-described method).

A computer program product, for example a computer program medium, can be provided or supplied, for example, as a storage medium, for example a memory card, a USB stick, a CD-ROM, a DVD, or else in the form of a downloadable file from a server in a network. For example, in a wireless communications network, this can be effected by transferring an appropriate file with the computer program product or the computer program means.

According to a further aspect, a controller for producing an optical system for a lithography apparatus is proposed. The controller comprises:
a provision device for carrying out step a) of the method described above,
a first ascertainment device for carrying out step b) of the method described above, and
a second ascertainment device for carrying out step c) of the method described above.

The respective unit, for example the controller, the provision device, the first and second ascertainment devices, can be implemented with hardware technology and/or software technology. If the implementation is in hardware, the respective unit can be in the form of an apparatus or part of an apparatus, such as a computer or a microprocessor, or in the form of a control computer. In the case of an implementation in terms of software technology, the respective unit can be embodied as a computer program product, as a function, as a routine, as part of a program code or as an executable object.

According to a further aspect, a method for producing an optical system for a lithography apparatus is proposed. The optical system comprises an optical component having a substrate which is cut out of a raw block. Furthermore, the method comprises the following steps:
a) providing a distribution function for a zero-crossing temperature of a coefficient of thermal expansion of the raw block as a function of a location of the raw block, the distribution function being rotationally symmetric with respect to an axis of symmetry of the raw block,
b) ascertaining, in computer-implemented fashion, for the provided distribution function and each of a plurality of positions of a cutout region of the raw block that differ from one another, a measure of an inhomogeneity of the zero-crossing temperature of the cutout region, with the plurality of positions of the cutout region differing from one another in relation to a radial position and/or a height position of the raw block, and
c) ascertaining an optimal position of the cutout region as the position from the plurality of positions for which the ascertained measure of inhomogeneity is minimal.

The measure of inhomogeneity of the zero-crossing temperature of the cutout region for example comprises a parameter of a distribution function of the zero-crossing temperature of the cutout region. In particular, the distribution function of the zero-crossing temperature of the cutout region is a function of the location of the cutout region. Furthermore, the distribution function of the zero-crossing temperature of the cutout region is, in particular, a subset of the distribution function of the zero-crossing temperature of the raw block for the respective cutout region.

For example, the parameter for the measure of inhomogeneity of the zero-crossing temperature of the cutout region comprises a deviation from a nominal value ascertained in advance, an ascertained mean value and/or an ascertained median value of the distribution function of the cutout region and/or a deviation from a nominal distribution function of the zero-crossing temperature ascertained in advance.

For example, a statistical distribution function of the zero-crossing temperature of the cutout region can be ascertained on the basis of the distribution function of the zero-crossing temperature of the cutout region, which is a function of the location of the cutout region. For example, a mean value of the zero-crossing temperature, a median value of the zero-crossing temperature and/or a (statistical) standard deviation is ascertained on the basis of the statistical distribution function of the zero-crossing temperature of the cutout region. In that case, the parameter for the measure of inhomogeneity of the zero-crossing temperature of the cutout region for example has a deviation from the ascertained mean value, the ascertained median value and/or the standard deviation.

“A (n)” should not necessarily be understood as a restriction to exactly one element in the present case. Rather, a plurality of elements, for example two, three or more, may also be intended. Nor should any other numeral used here be understood to the effect that there is a restriction to exactly the stated number of elements. Rather, unless indicated otherwise, numerical deviations upwards and downwards are possible.

The embodiments and features described for the method according to the first aspect are correspondingly applicable to the further proposed aspects and vice versa.

Further possible implementations of the invention also comprise non-explicitly mentioned combinations of features or embodiments described previously or hereinafter with regard to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in detail hereinafter on the basis of preferred embodiments with reference to the accompanying figures.

### BRIEF DESCRIPTION OF THE DRAWINGS

FIG. 1 shows a schematic meridional section of a projection exposure apparatus for EUV projection lithography, according to one embodiment;

FIG. 2 shows an optical system of the projection exposure apparatus from FIG. 1 according to one embodiment, the optical system comprising an optical component;

FIG. 3 shows a flowchart of a method for producing an optical system of the projection exposure apparatus from FIG. 1, according to one embodiment;

FIG. 4 shows a perspective view of a raw block for producing a substrate of the optical component from FIG. 2, according to one embodiment;

FIG. 5 shows a plan view of the raw block from FIG. 4, according to one embodiment;

FIG. 6 shows a further plan view of the raw block from FIG. 4, according to one embodiment;

FIG. 7 shows a further plan view of the raw block from FIG. 4, according to one embodiment;

FIG. 7A shows a detail from FIG. 7;

FIG. 8 shows a cross-sectional view of the raw block from FIG. 4, according to one embodiment;

FIG. 8A shows a detail from FIG. 8;

FIGS. 8B to 8E each show respective cutout regions and respective tolerance regions from FIG. 8A, together with one or more respective deviation cutout regions of the corresponding cutout region;

FIG. 9 shows a further cross-sectional view of the raw block from FIG. 4, according to one embodiment;

FIG. 9A illustrates an aberration of the optical system from FIG. 2 in comparison with a threshold value;

FIG. 10 elucidates an individual error of the imaging process of the optical system from FIG. 2, ascertained in computer-implemented fashion, according to one embodiment;

FIG. 11 elucidates a further individual error of the imaging process of the optical system from FIG. 2, ascertained in computer-implemented fashion, according to one embodiment;

FIG. 12 elucidates a setting of an illumination with operating light of the optical component from FIG. 2, according to one embodiment;

FIG. 12A elucidates a heating of the optical component from FIG. 2, according to one embodiment;

FIG. 12B elucidates a heating pattern applied during the heating in FIG. 12A, according to one embodiment;

FIG. 13 shows a substrate produced using the method from FIG. 3, according to one embodiment; and

FIG. 14 shows a further substrate produced using the method from FIG. 3, according to a further embodiment.

### DETAILED DESCRIPTION

Unless indicated otherwise, elements that are identical, equivalent or functionally identical or analogous have been provided with the same reference signs in the figures. Furthermore, it should be noted that the illustrations in the figures are not necessarily true to scale.

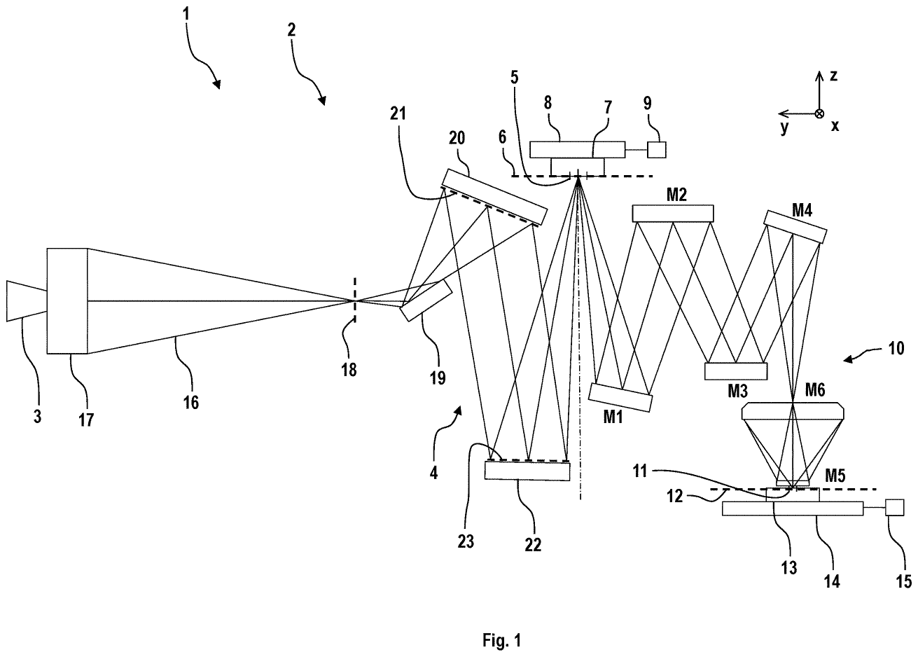

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by a wafer displacement drive 15, in particular in the y-direction y. The displacement firstly of the reticle 7 by the reticle displacement drive 9 and secondly of the wafer 13 by the wafer displacement drive 15 can be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 can be a plasma source, for example an LPP (laser produced plasma) source or a GDPP (gas discharge produced plasma) source. It can also be a synchrotron-based radiation source. The light source 3 can be a free electron laser (FEL).

The illumination radiation 16 emanating from the light source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect going beyond the pure deflection effect. In an alternative to that or in addition, the deflection mirror 19 can be designed as a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are shown in FIG. 1 by way of example.

The first facets 21 can be embodied as macroscopic facets, in particular as rectangular facets or as facets with an arcuate or part-circular edge contour. The first facets 21 can be in the form of plane facets or alternatively in the form of convexly or concavely curved facets.

As is known for example from DE 10 2008 009 600 A1, the first facets 21 themselves can also each be composed of a multiplicity of individual mirrors, in particular a multiplicity of micromirrors. In particular, the first facet mirror 20 can be in the form of a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is again made to DE 10 2008 009 600 A1.

The second facets 23 can have plane reflection surfaces or, alternatively, convexly or concavely curved reflection surfaces.

The illumination optical unit 4 thus forms a double-faceted system. This fundamental principle is also referred to as a fly's eye integrator.

It may be advantageous to arrange the second facet mirror 22 not exactly within a plane that is optically conjugate to a pupil plane of the projection optical unit 10. In particular, the second facet mirror 22 can be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or else, alternatively, two or more mirrors, which are arranged in succession in the beam path of the illumination optical unit 4. The transfer optical unit might in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 with the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of free-form faces without an axis of rotational symmetry. Alternatively, the reflection surfaces of the mirrors Mi can be designed as aspherical faces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y can be of approximately the same magnitude as a z-distance between the object plane 6 and the image plane 12.

In particular, the projection optical unit 10 can have an anamorphic design. It has in particular different imaging scales ßx, ßy in the x- and y-directions x, y. The two imaging scales ßx, ßy of the projection optical unit 10 are preferably (ßx, ßy)=(+/−0.25, +/−0.125). A positive imaging scale 6 means imaging without image inversion. A negative sign for the imaging scale 8 means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and γ-direction y are known from US 2018/0074303 A1.

In each case, one of the second facets 23 is assigned to exactly one of the first facets 21 for forming in each case an illumination channel for illuminating the object field 5. This can in particular result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are imaged respectively onto the reticle 7, overlaid on one another to illuminate the object field 5. The illumination of the object field 5 is in particular as homogeneous as possible. It preferably has a uniformity error of less than 2%. Field uniformity can be achieved by superimposing different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, in particular the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and in particular of the entrance pupil of the projection optical unit 10 are described below.

The projection optical unit 10 may have a homocentric entrance pupil in particular. This pupil can be either accessible or inaccessible.

The entrance pupil of the projection optical unit 10 regularly cannot be exactly illuminated with the second facet mirror 22. In the case of an imaging process of the projection optical unit 10, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. In particular, this area exhibits a finite curvature.

It may be the case that the projection optical unit 10 has different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different positions of the tangential entrance pupil and the sagittal entrance pupil can be taken into account.

In the arrangement of the component parts of the illumination optical unit 4 illustrated in FIG. 1, the second facet mirror 22 is arranged in an area conjugate to the entrance pupil of the projection optical unit 10. The first facet mirror 20 is arranged tilted in relation to the object plane 6. The first facet mirror 20 is arranged tilted in relation to an arrangement plane defined by the deflection mirror 19. The first facet mirror 20 is arranged tilted in relation to an arrangement plane defined by the second facet mirror 22.

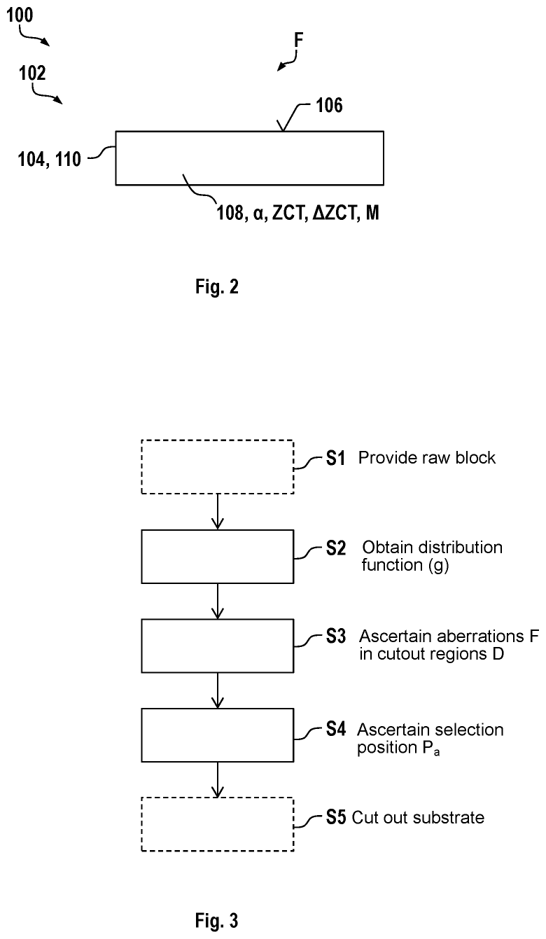

FIG. 2 shows an optical system 100 (e.g. a part of an optical system 100) having an optical component 102 according to one embodiment. The optical component 102 comprises a substrate 104 and an optically active surface 106. For example, the optical component 102 is a mirror having a mirror substrate 104 and a reflective surface 106.

For example, the optical system 100 is a projection optical unit 10 of the EUV lithography apparatus 1 (FIG. 1). However, the optical system 100 might also be an illumination optical unit 4 of the lithography apparatus 1, for example.

For example, the optical component 102 is one of the mirrors M1 to M6 of the projection optical unit 10 (FIG. 1). For example, the optical component 102 can also be one of the mirrors 19, 20, 22 of the illumination optical unit 4 (FIG. 1).

Although not shown in the figures, the optical component 102 might also be a mirror or a lens element of a DUV lithography apparatus.

The optical component 102 can heat up due to irradiation by operating light 16 (e.g. EUV light 16 of the lithography apparatus 1, FIG. 1) and absorption of the operating light 16. This can lead to a thermal deformation of the optical component 102. Aberrations F of the optical component 102 or of the optical system 100 comprising the optical component 102 might arise on account of this thermal deformation.

High-quality substrate material 108 is used for the substrate 104 in order to reduce thermal deformation and aberrations F connected therewith. In particular, the material 108 of the substrate 104 has a very small coefficient of thermal expansion α. In particular, the material 108 has a zero-crossing temperature ZCT of the coefficient of thermal expansion α at which a thermal deformation of the mirror material 108 on account of a temperature increase is minimal and/or zero.

The zero-crossing temperature ZCT of the substrate 104 is not distributed homogeneously over a substrate body 110 of the substrate 104 on account of inhomogeneities in the material 108 of the substrate 104; instead, it has fluctuations ΔZCT as a function of a location of the substrate body 110. A value of a mean zero-crossing temperature M of the substrate material 108 and fluctuations ΔZCT of the zero-crossing temperature ZCT as a function of the location have a direct influence on aberrations F of the optical component 102, and hence of the optical system 100 with the optical component 102.

A method for producing an optical system 100 for a lithography apparatus 1 is described below with reference to FIGS. 3 to 12. The optical system 100 comprises the optical component 102 with the optically active surface 106 and the substrate 104 (FIG. 2).

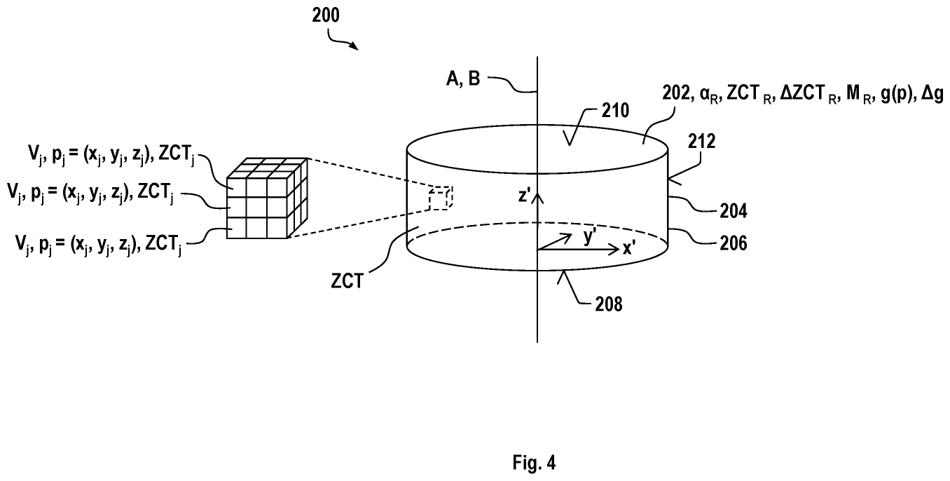

A raw block 200 (FIG. 4) is provided in a first optional step S1 of the method. The substrate 104 (FIG. 2) can be cut out of the raw block 200 over the course of the method.

The raw block 200 is produced from a material 202 with a very small coefficient of thermal expansion α_{R}. In particular, the material 202 has a zero-crossing temperature ZCT_{R} of the coefficient of thermal expansion α_{R} at which a thermal deformation of the material 202 on account of a temperature increase is minimal and/or zero.

The zero-crossing temperature ZCT_{R} of the raw block 200 is not distributed homogeneously over a body 204 of the raw block 200 on account of inhomogeneities in the material 202 of the raw block 200; instead, it has fluctuations ΔZCT_{R} about a mean zero-crossing temperature MR as a function of a location p of the raw block body 204.

For example, the raw block 200 is produced in a direct deposition process or in a soot process.

A distribution function g(p) of the zero-crossing temperature ZCT_{R} of the raw block 200 is provided in a second step S2 of the method.

The distribution function g(p) of the zero-crossing temperature ZCT_{R} of the raw block 200 is for example measured in step S2. However, the distribution function g(p) of the zero-crossing temperature ZCT_{R} of the raw block 200 can for example also be ascertained in computer-aided fashion on the basis of parameters of the raw block 200.

A provided distribution function g(p) of the zero-crossing temperature ZCT_{R} of the raw block 200 for example specifies a value ZCTj of the zero-crossing temperature ZCT_{R} for each location pj of the raw block 200. By way of example, FIG. 4 shows an enlarged detail of the raw block 200 which elucidates a plurality of volume elements Vj of the raw block 200. As an example, the enlarged detail of the raw block 200 shows 27 (3×3×3) volume elements Vj, three of which have been provided with a reference sign. Moreover, for each volume element Vj, FIG. 4 labels a location pj of the corresponding volume element Vj in the coordinates xj, yj, zj of the shown Cartesian coordinate system x′, y′, z′. For example, in a manner assigned to each location pj of the raw block 200, a zero-crossing temperature ZCTj of this location pj is provided and/or measured in step S2.

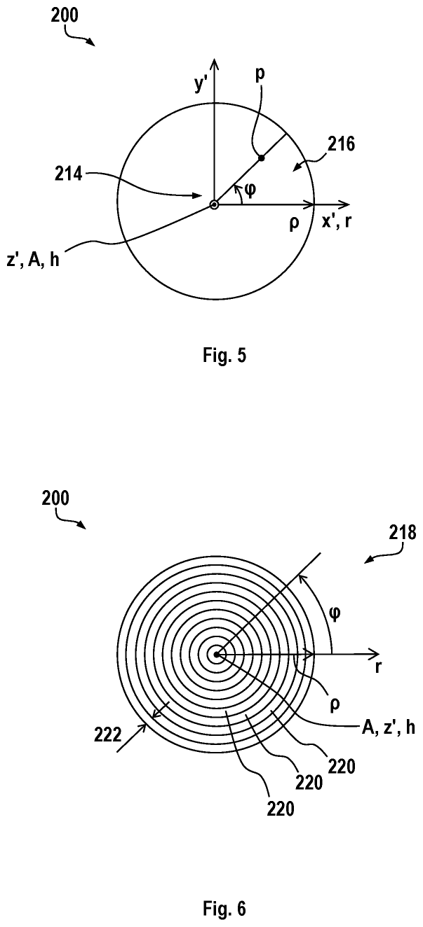

In the present case, the distribution function g(p) of the raw block 200 is rotationally symmetric with respect to an axis of symmetry A of the raw block 200 in particular. This means that the distribution function g(p) of the zero-crossing temperature ZCT_{R} of the raw block 200 is mapped onto itself for rotations through any desired angle (azimuth angle φ, FIG. 5) about the axis of symmetry A.

Optionally, an error range Δg of the distribution function g(p) of the zero-crossing temperature ZCT_{R} of the raw block 200 can also be provided in step S2.

As shown in FIG. 4, the raw block 200 for example has a cylindrical shape 206, e.g. the shape 206 of a right circular cylinder. The raw block 200, i.e. the cylindrical shape 206 of the raw block 200, has a cylinder axis B corresponding to the axis of symmetry A. Furthermore, the raw block 200 or its cylindrical shape 206 has two opposite end faces 208, 210 (e.g. circular surfaces 208, 210) and a lateral surface 212.

In FIG. 4, a location p of the raw block 200 (e.g. pj=xj, yj zj) is described in exemplary fashion with a Cartesian coordinate system 214 on the basis of Cartesian coordinates x′, y′, z′.

FIG. 5 shows a plan view of the raw block 200 from FIG. 4, together with the Cartesian coordinate system 214 and a cylindrical coordinate system 216.

As elucidated by FIG. 5, a location p of the raw block 200 can also be described using a cylindrical coordinate system 216 (cylinder coordinates ρ, φ, z′)—rather than the Cartesian coordinate system 214. In the example shown in FIG. 5, the z′-axes of the Cartesian coordinate system 214 and cylindrical coordinate system 216 correspond to one another. Moreover, in FIG. 5, the x′-axis of the Cartesian coordinate system 214 is aligned in the φ-equal-to-zero (φ=0) direction, and the angle φ increases from the x′-axis to the γ′-axis.

A radial direction r (FIG. 5) of the raw block 200 is arranged, in particular, along the cylinder coordinate ρ and all directions created from the cylinder coordinate ρ by rotation through the angle φ. Moreover, a height direction h (FIG. 5) of the raw block 200 is arranged along the Cartesian and cylinder axis z′.

The distribution function g(p) of the zero-crossing temperature ZCT_{R} of the raw block 200 being rotationally symmetric with respect to the axis of symmetry A of the raw block 200 means that the zero-crossing temperature ZCT_{R} of the raw block 200 has a pattern 218, as elucidated in FIG. 6. In particular, the pattern 218 comprises concentric rings 220 (in particular circular rings 220), which are arranged concentrically about the axis of symmetry A. In FIG. 6, three of the rings 220 have been labelled with a reference sign by way of example. Moreover, with respect to a ring width 222, the rings 220 have been depicted in exaggeratedly large fashion in FIG. 6 for reasons of clarity.

The zero-crossing temperature ZCT_{R} does not change along a respective ring 220. In other words, the distribution function g(p) of the zero-crossing temperature ZCT_{R} of the raw block 200 has azimuthal symmetry with respect to the azimuth angle φ.

By contrast, the zero-crossing temperature ZCT_{R} of the raw block 200 changes in the radial direction r. Moreover, the zero-crossing temperature ZCT_{R} of the raw block 200 also changes in the height direction h.

In a third step S3 of the method there is a computer-implemented examination of various cutout regions Dᵢ of the raw block 200 for cutting out the substrate 104 of the optical component 102 (FIG. 2) from the raw block 200.

In particular, a computer-implemented simulation is performed in step S3 for the provided distribution function ZCT_{R} of the raw block 200 and each of a plurality of positions Pi of a cutout region D₁ of the raw block 200 that differ from one another. In particular, a total number of n positions Pi of the cutout region Di that differ from one another are provided. Herein, n is a natural number greater than 1, and i denotes an index that runs from 1 to n. An aberration Fi of an optical component 102 produced on the basis of the respective cutout region Di and/or of the optical system 100 having the corresponding optical component 102 is ascertained within the scope of the simulation. That is to say, Fi is a simulation-ascertained aberration for the i-th of the n provided positions Pi of the cutout region Di. In other words, a total number of n different aberrations Fi are ascertained during the simulation.

That is to say, the distribution function g(p) of the zero-crossing temperature ZCT_{R} of the raw block 200 provided in step S2 and each of the plurality of positions Pi (n in total) of the cutout region Di of the raw block 200 that differ from one another are input parameters for the simulation calculation of step S3. Moreover, the ascertained aberrations Fi (n in total) are output parameters of the simulation calculation.

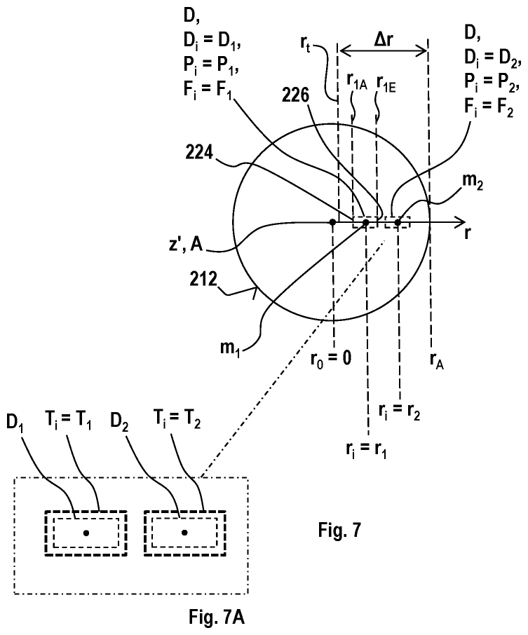

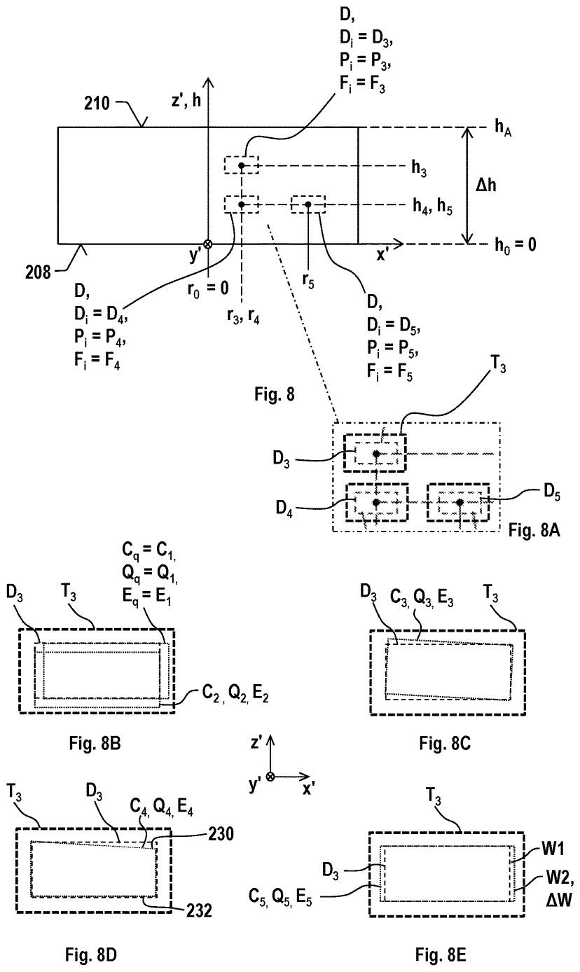

FIGS. 7 and 8 illustrate different positions Pi of the cutout region Di, which are used as input variables for the simulation. In particular, the aberration Fi is ascertained for a plurality of positions Pi of the cutout region D which differ from one another in terms of a radial position ri and/or a height position hi of the raw block 200.

FIG. 7 shows a plan view of the raw block 200 of FIG. 4. Moreover, two different positions Pi of a cutout region Di which differ from one another in relation to a radial position ri are illustrated as an example. In particular, the radial position ri is a position along the radial direction r of the raw block 200. Moreover, the radial direction r extends from a radius r0 equal to zero (r0=0) at the axis of symmetry A of the raw block 200 to an outer radius rA at the lateral surface 212 (FIG. 4) of the raw block 200.

A first exemplary position P1 of a first cutout region D1 is situated at a radial position r1. Moreover, a second exemplary position P2 of a second cutout region D2 is situated at a radial position r2. By way of example, a position of an (e.g. geometric) centre m1, m2 of a respective cutout region D1, D2 is labelled as a position P1, P2 of the respective cutout region D1, D2 in FIG. 7. However, a position Pi of a cutout region Di might also include positions r1A, r1E of outer edges 224, 226 of the respective cutout region Di, as illustrated by way of example for the cutout region D1 in FIG. 7.

Each of the n cutout regions Di (e.g. D1, D2) can be chosen (i.e. arranged within the raw block 200) to be free from the axis of symmetry A. In other words, the respective cutout region Di for example does not contain the axis of symmetry A. That is to say, the various positions Pi of the cutout regions Di (for example also the positions of outer edges 224, 226 of the cutout regions Di) are each situated at a radius r1, r2 greater than zero, as shown in FIG. 7.

Instead of or in addition to different radial positions (FIG. 7), the plurality of positions Pi of the plurality of cutout regions Di might also have different height positions h1, h2, as shown in FIG. 8.

In the example of FIG. 8, a third exemplary position P3 of a third cutout region D3 is situated at a radial position r3 and a height position h3. Furthermore, a fourth exemplary position P4 of a fourth cutout region D4 is situated at a radial position r4 and a height position h4. Moreover, a fifth exemplary position P5 of a fifth cutout region D5 is situated at a radial position r5 and a height position h5. That is to say, in the example of FIG. 8, the cutout regions D3 and D4 have the same radial position r3, r4 (r3=r4) but different height positions h3, h4. Moreover, the cutout regions D4 and D5 have the same height position h4, h5 (h4=h5) but different radial positions r4, r5.

The positions Pi of the cutout regions Di shown in FIGS. 7 and 8 and used as input parameters for the simulation in step S3 should merely be considered to be examples of different positions Pi in relation to the radial position ri and the height position hi. Many other positions Pi of the cutout regions Di in relation to the radial position ri and the height position hi are possible within the raw block 200.

or example, the positions Pi of the cutout regions Di can cover a radial range Δr (FIG. 7) of the raw block 200 from an inner radius rt adjacent to the axis of symmetry A to an outer radius rA at the lateral surface 212 of the raw block 200. In other words, the radial positions rᵢ of the cutout regions Dᵢ can cover the entire radial range Δr of the raw block 200, apart from the axis of symmetry A.

In addition to that or instead, the positions Pi of the cutout regions Di can for example cover a height range Δh of the raw block 200 from the first end face 208 (h0=0, FIG. 8) to the second end face 210 of the raw block 200 (hA, FIG. 8). In other words, the height positions hi of the cutout regions Di can cover the entire height Δh of the raw block 200.

FIGS. 7 and 8 show different positions Pi of the cutout regions Di in relation to the radial position ri and the height position hi.

In addition thereto, the plurality of positions Pi of the cutout regions Di can also differ from one another in relation to a rotation with respect to one or more rotational degrees of freedom, e.g. a rotation about the x′-direction x′ (first direction), the y′-direction y′ (second direction) and/or the z′-direction z′ (third direction). In particular, the third direction z′ of the raw block 200 is arranged along (i.e. in correspondence with) the axis of symmetry A of the raw block 200. In particular, the first and second direction x′, y′ are arranged perpendicular to one another and in each case perpendicular to the axis of symmetry A.

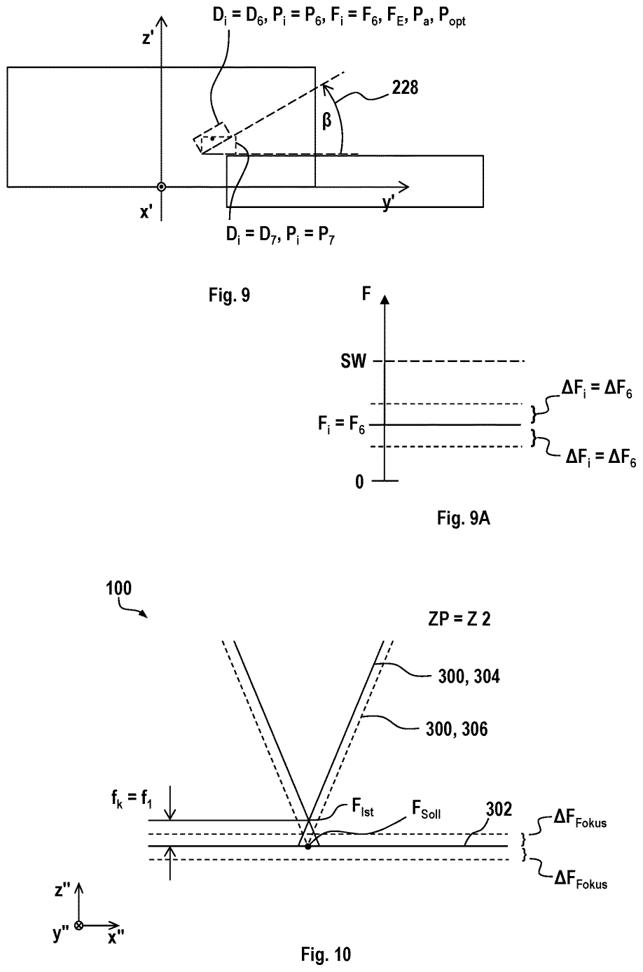

As an example, FIG. 9 shows positions P6, P7 of two cutout regions D6, D7 which differ from one another in relation to a rotation about the x′-direction x′ (first direction). In particular, the position P6 is rotated through the angle ß relative to the position P7 in FIG. 9.

Although not shown in the figures, the plurality of positions Pi of the cutout region D can also differ from one another in relation to a rotation about the γ′-direction y′ (second direction) and/or the z′-direction z′ (third direction).

As elucidated in FIGS. 7A and 8A to 8E, one or more deviation aberrations Eq from one or more deviation positions Q_{q} of the cutout region D can also be taken into account for each of the plurality of positions Pi, which differ from one another, of the corresponding cutout regions Di, in addition to the aberration Fi for the corresponding position Pi. This can give consideration to imprecision when the substrate 104 is subsequently cut out of the raw block 200 (step S5).

For the exemplary cutout regions D1 and D2, FIG. 7A shows a respective tolerance region Ti=T1 and Ti=T2. Moreover, a respective tolerance region T3 is shown in FIG. 8A for the exemplary cutout regions D3 to D5 (without reference signs for D4 and D5). Although not shown in FIG. 9, a respective corresponding tolerance region can also be provided for the cutout regions D6 and D7.

As shown by way of example in FIGS. 8B to 8E for the cutout region D3 with the tolerance region T3, one or more deviation positions Q_{q} of the corresponding cutout region D3 can now be taken into account. In particular, the deviation positions Q_{q} of the corresponding cutout region D3 are chosen such that the deviation cutout regions Cq defined thereby are located within the tolerance region T3. Herein, q denotes an index, running from 1 to the total number of deviation positions Q_{q}.

FIG. 8B elucidates two deviation positions Q1 and Q2 of the cutout region D3. The deviation positions Q1 and Q2 differ from the position P3 of the cutout region D3 in terms of a displacement in the first direction x′ (Q1) and a displacement in the third direction z′ (Q2). Although not shown, a deviation position can differ from the position P3 of the cutout region D3 in terms of a displacement in the second direction y′ as well.

FIG. 8C elucidates a further deviation position Q3 of the cutout region D3. The deviation position Q3 differs from the position P3 of the cutout region D3 in terms of a rotation about the second direction y′. Although not shown, a deviation position can differ from the position P3 of the cutout region D3 in terms of a rotation about the first and/or third direction x′, z′ as well.

FIG. 8D elucidates a further deviation position Q4 of the cutout region D3. The deviation position Q4 differs from the position P3 of the cutout region D3 in terms of non-parallel edges 230, 232 (i.e. outer edges) of the deviation cutout region C4 in the first direction x′. Although not shown, edges of a deviation cutout region can also be non-parallel in the second and/or third direction y′, z′.

FIG. 8E elucidates a further deviation position Q5 of the cutout region D3. The deviation position Q5 differs from the position P3 of the cutout region D3 in terms of a volume deviation ΔW (e.g. ΔW=W2−W1) of the deviation cutout region C5 from the cutout region D3. Other volume deviations to those shown (e.g. in other directions x′, y′, z′) can also be taken into account.

All types of deviation positions Qi (e.g. Q1 to Q5) and deviation cutout regions Ci (e.g. C1 to C5) shown (FIGS. 8B to 8E) and/or described herein can be combined with one another as desired in order to create further deviation positions Qi and deviation cutout regions Ci.

Next, a corresponding deviation aberration Ei can be ascertained for each considered deviation position Qi (e.g. Q1 to Q5) of each cutout region Di (i.e. for each deviation cutout region Ci).

Then, the at least one selection position Pa of the cutout region D can be ascertained as the position from the plurality of positions Pi for which the ascertained aberration Fi and the one or more ascertained deviation aberrations Eq (e.g. E1 to E5) are each less than a predetermined threshold value SW (FIG. 9A).

Optionally, each error Fi (and each error Eq, if applicable) can be ascertained in step S3 on the basis of a plurality of individual errors fₖ that differ from one another (FIG. 10). In particular, a plurality of individual errors fₖ which are associated with error types of the imaging process of the optical system 100 that differ from one another can be used for the ascertainment of each error Fi (and of each error Eq, if applicable).

For example, the individual errors fₖ that differ from one another are taken into account as relative error values. In this variant of step S3, the error Fi (and the error Eq, if applicable) of the imaging process of the optical system 100 can for example be ascertained as a maximum of the plurality of ascertained individual errors fₖ, e.g. on the basis of the following equation:

$${F}_{i} = max ( {f}_{k} ) , for i = 1 to n and k = 1 to m$$

In this case, fₖ denotes the (e.g. relative) individual errors for the provided distribution function g(p) and a specific position Pi of the cutout region D. In this case, k is an index which runs from 1 to m, where m is a natural number greater than 1 and denotes the total number of individual errors fₖ that differ from one another.

In other examples, the error Fi of the imaging process of the optical system 100 can also be ascertained in step S3 as a mean value, a median and/or a quantile of the plurality of ascertained individual errors fₖ.

The plurality of individual errors fₖ that differ from one another can relate to, for example, a deviation of an actual focus F₁ₛₜ of the optical system 100 from a target focus F_{Soll} (defocus, spherical aberration, Zernike polynomial ZP of Z 2), as elucidated in FIG. 10. FIG. 10 shows a radiation 300 (e.g. the operating light 16 in FIG. 1), which is incident on an image plane 302 of the optical system 100 (FIG. 2). The target focus F_{Soll} is located in the image plane 302 in particular. The actual focus first deviates from the target focus F_{Soll}, and so the image is blurry. A deviation of the actual focus first from the target focus Fsoll represents an example of an individual error fₖ, e.g. a first (k=1) individual error f1.

Furthermore, FIG. 10 plots an error range ΔF_{fokus} as an example of a threshold value SW (FIG. 9A) and/or individual threshold value. For example, an actual focus located in the range F_{Soll}±ΔF_{fokus} is an aberration Fᵢ that is less than the threshold value SW. However, the actual focus F₁ₛₜ shown in FIG. 10 is no longer located in the range F_{Soll}±ΔF_{fokus}, and the associated position Pᵢ of a corresponding cutout region Dᵢ therefore does not fulfil the condition for a selection position Pₐ. Exemplary values of an error range ΔF_{fokus} that corresponds to a threshold value SW and/or an individual threshold value for the focus for example comprise 15 nm or less, 10 nm or less and/or 5 nm or less.

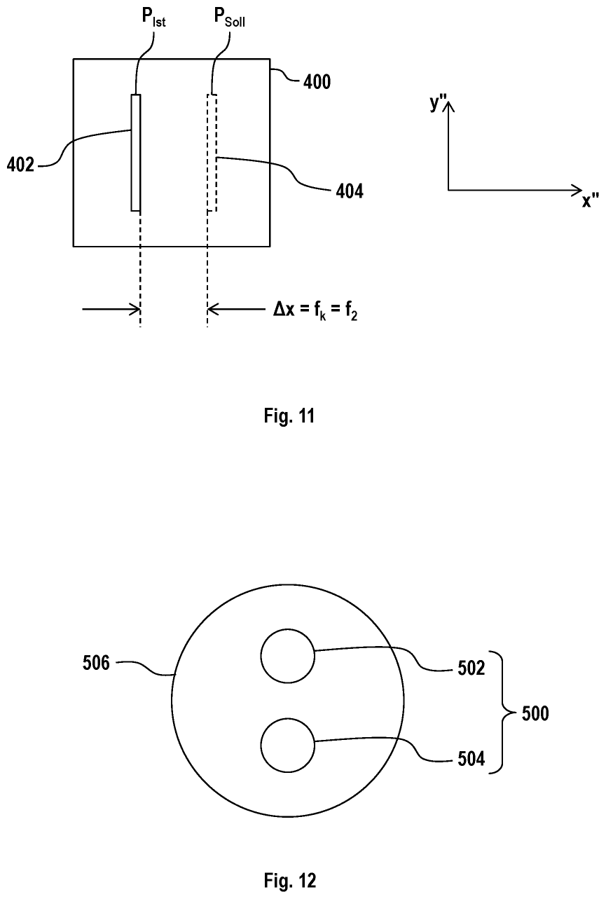

For example, the plurality of individual errors fₖ that differ from one another can also relate to a displacement of a wavefront (e.g. 304 in FIG. 10) relative to a target wavefront 306, with the result that an actual position PIst of an object 402 imaged in an image 400 (FIG. 11) in an image plane 302 (FIG. 10) of the optical system 100 with the aid of the optical system 100 deviates from a target position PSoll of the imaged object 404, as elucidated in FIG. 11. A deviation of the actual position PIst from the target position PSoll (overlay error) represents a further example of an individual error fₖ, e.g. a second (k=2) individual error f2.

In addition to or instead of individual errors fₖ in relation to the error types that differ from one another, the plurality of individual errors fₖ that differ from one another can also relate to individual errors fₖ in relation to setting parameters of an illumination of the optical component 102, to be produced, of the optical system 100 that differ from one another.

For example, the various setting parameters of the planned illumination of the optical component 102 to be produced comprise a radiation intensity of an operating light (e.g. EUV light 16, FIG. 1), which is radiated onto the optical component 102.

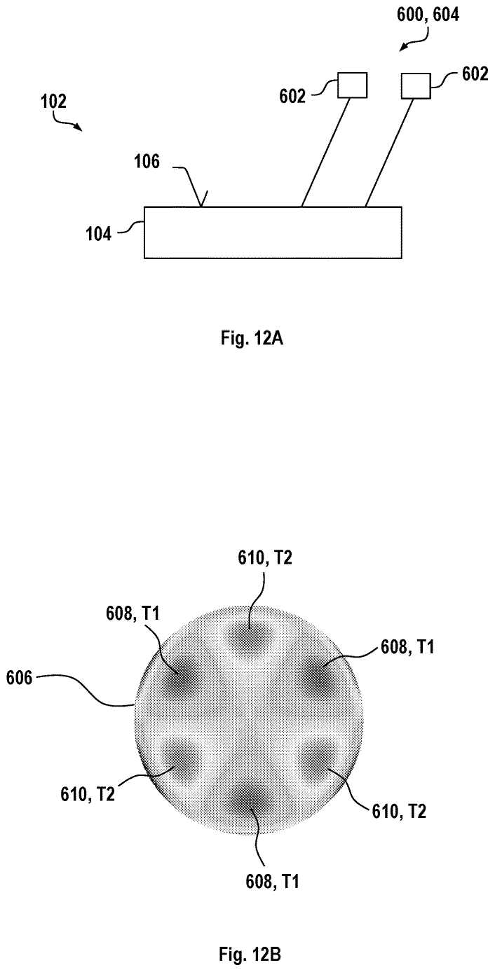

For example, the various setting parameters of the illumination can also comprise a pattern 500 or heat flux distribution 500, in which or with which the operating light 16 is radiated onto the optical component 102. By way of example, FIG. 12 elucidates two heat flux poles 502, 504 (dipole pattern) of a heat flux distribution 500 of an optically active surface 506 of an optical component (e.g. the optical component 102 in FIG. 2).

In addition to or instead of individual errors fₖ in relation to the error types that differ from one another, the plurality of individual errors fₖ that differ from one another can also relate to individual errors fₖ in relation to setting parameters 604 of a heating of the optical component 102, to be produced, by an external heating device 600 that differ from one another. FIG. 12A elucidates the optical component 102 from FIG. 2 with the substrate 104 and the optically active surface 106. Moreover, FIG. 12A shows an external heating device 600 for heating the optical component 102. For example, the external heating device 600 comprises a plurality of radiant heaters 602. Two radiant heaters 602 are shown in FIG. 12A by way of example; however, more than two radiant heaters 602 might also be provided. A radiant heater array can also be provided. Moreover (although this is not shown in the figures), the heating device 600 can also be configured to heat the optical component 102 through thermal conduction-rather than heating radiation, i.e. thermal radiation, as shown.

Heating of the optical component 102, to be produced, by the external heating device 600 can be implemented in accordance with various setting parameters 604 of the heating device 600. For example, the various setting parameters 604 comprise a temperature T1, T2, to which the optical component 102 (or regions thereof, see FIG. 12B) is heated. For example, the various setting parameters 604 also comprise a heating pattern 606 that is used during heating. In particular, the heating pattern 606 is a temperature pattern that should be realized in the optical component 102. In particular, the heating pattern 606 is a two-dimensional or three-dimensional spatially dependent target temperature map of the optical component 102. In particular, various heating patterns 606 to be applied can be taken into account when ascertaining the individual errors fₖ. A respective heating pattern 606 is selected such that it is suitable for correcting a specific one of the various error types of the imaging process. How well a specific error type can be corrected by a heating pattern 606 adapted to this end depends, inter alia, on the distribution of the zero-crossing temperature ZCT of the substrate 104. For example, the compression temperature domain is located between an ambient temperature and approximately twice the temperature difference between the ambient temperature and the zero-crossing temperature ZCT in the spatial region of the substrate 104 in which the compression is intended to be applied. For example, the expansion temperature domain extends from beyond the compression temperature domain to warmer temperature regions. The size of these temperature domains, in particular the size of the compression temperature domain, determines a correction potential for one or more error types of the imaging process by heating with the external heating device 600.

FIG. 12B shows an example of planned heating of the optical component 102, to be produced, by the external heating device 600 (FIG. 12A) in accordance with an exemplary heating pattern 606. For example, the example of a heating pattern 606 shown in FIG. 12B is used to correct a Zernike Z20 aberration and/or an aberration according to the Zernike polynomial Z 5, ±3. The heating pattern 606 has three regions 608 (sectors 608) with a first target temperature T1 and three regions 610 (sectors 610) with a second target temperature T2. In particular, the first target temperature T1 is a temperature at which a material of the optical component 102 is compressed locally. Moreover, in particular, the second target temperature T2 is a temperature at which a material of the optical component 102 is expanded locally. The regions 608 are compressed and the regions 610 are expanded by heating in accordance with the heating pattern 606. Hence, the optical component 102 is deformed so that a desired wavefront effect is achieved for the purpose of correcting the corresponding aberration.

The heating pattern 606 in FIG. 12B is only one example for elucidating the heating with the heating device 600 in FIG. 12A. Instead of the heating pattern 606 or in addition thereto, any other heating pattern suitable for correcting an aberration can be taken into account in the computer-implemented ascertainment of the individual errors fₖ.

Although not shown in the figures, the plurality of ascertained individual errors fₖ can be weighted in accordance with predetermined weights. As a result, the individual errors fₖ can be weighted depending on a planned use of the optical component 102 to be produced and of the optical system 100 having this component 102.

For example, the following adjustment function can be applied for the purpose of ascertaining the aberrations Fᵢ (and the deviation aberrations Eq, if applicable) in step S3:

$${F}_{E} = min {‖ {W}_{ref} + {\sum }_{l} {p}_{l} Δ {W}_{l} ‖}^{2}$$

Here, W_{ref} denotes a reference wavefront. For example, the reference wavefront comprises a vector of a Zernike coefficient which comprises all illumination settings (heat load cases) of the optical system 100 for the case that the cutout region D is ascertained only on the basis of a radial displacement (FIG. 7) and a height displacement (FIG. 8) of the position Pᵢ of the cutout region Dᵢ (i.e. without rotation, FIG. 9). For example, the reference wavefront comprises a vector of a Zernike coefficient which also considers time series of use cases of the optical component 102 of the optical system 100.

Furthermore, sensitivities are defined as follows:

$$Δ {W}_{l} = W ( {p}_{l} ) - {W}_{ref}$$

Here, W(pl) denotes a wavefront obtained if a rotation 228 about the first, second and/or third axis x′, y′, z′ of the raw block 200 is also taken into account (FIG. 9) when choosing the cutout regions Di. The index l denotes the various optimization cases, for example a rotation 228 about the first, second and/or third axis x′, y′, z′ of the raw block 200 (FIG. 9), a radial displacement (FIG. 7) and a height displacement (FIG. 8).

However, a different adjustment function to the one described above can also be applied in step S3 in other examples.

In a fourth step S4 of the method, at least one selection position Pa of the cutout region Di is ascertained as the position from the plurality of positions Pi for which the ascertained aberration Fi is less than a predetermined threshold value SW.

FIG. 9A illustrates an aberration Fi=F6 of the cutout region D6 (for i=6) from FIG. 9 by way of example. As evident from FIG. 9A, the aberration F6 of the cutout region D6 is less than the predetermined threshold value SW. Thus, the position P6 of the cutout region D6 is ascertained in step S4 as the at least one selection position Pa in this example.

As illustrated in FIG. 9A, an error range ΔFi of the ascertained aberration Fi can optionally be additionally ascertained during the computer-implemented ascertainment of the respective aberration Fi (and of the respective deviation aberration Eq, if applicable). In this case, the at least one selection position Pa of the cutout region D can be ascertained as the position from the plurality of positions Pi for which the ascertained aberration Fi, including its error range ΔFi, is less than the predetermined threshold value SW. In the example of FIG. 9A, the aberration F6 of the cutout region D6, including its error range ΔF6, is less than the predetermined threshold value SW. In particular, F6±ΔF6 is less than the predetermined threshold value SW.

Should no selection position Pa of the cutout region D be ascertained in step S4 because none of the ascertained aberrations Fi are less than the predetermined threshold value SW, then it may for example be established that the raw block 200 is not suitable for the production of a substrate 104. Step S5 is not carried out in this case.

Optionally, the at least one selection position Pa of the cutout region Di can also be an optimal position Pₒₚₜ of the cutout region Di for a minimal aberration Fi-instead of or in addition to being based on the threshold value SW. In other words, an optimal position Pₒₚₜ of the cutout region Di can also be ascertained in step S4 as the position from the plurality of positions Pi for which the ascertained aberration Fi is minimal.

For example, a minimum of the plurality of error values Fᵢ of the imaging process of the optical system 102 ascertained in step S3 is ascertained as final error F_{E}:

$${F}_{E} = min ( {F}_{i} ) , for i = 1 to n$$

Here, n is a natural number greater than 1 and denotes the number of aberrations Fi ascertained in step S3. Moreover, i is an index that runs from 1 to n.

Subsequently, the position Pi, associated with this minimum FE, of the cutout region Di is ascertained as the optimal position Pₒₚₜ of the cutout region Di for the production of the substrate 104 of the optical component 102.

Merely by way of example, the position Pi=P6 shown in FIG. 9 is labelled as a position whose associated ascertained individual error Fi=F6 was ascertained as a minimum error FE of all ascertained individual errors Fi for all provided positions Pi. Hence, the position P6 associated with this individual error F6 is ascertained as the optimal position Pₒₚₜ of the cutout region Di in this example.

In a fifth step S5 of the method, the substrate 104 (FIG. 2) is cut out of the raw block 200 (FIG. 4) according to the at least one ascertained selection position Pₐ of the cutout region Dᵢ and/or the optimal position Pₒₚₜ of the cutout region Dᵢ.

For the production of a substrate 104 of an optical component 102, the method makes it possible to cut a region out of the blank 200 in accordance with an advantageous and/or optimal ascertained cutout region D (i.e. the at least one selection position Pa and/or the optimal position Pₒₚₜ of the cutout region D). In particular, it is possible to choose a cutout region D which has an advantageous distribution of the zero-crossing temperature ZCT. As a result, aberrations F of the optical system 100 on account of thermal expansion of the substrate 104 can be reduced.

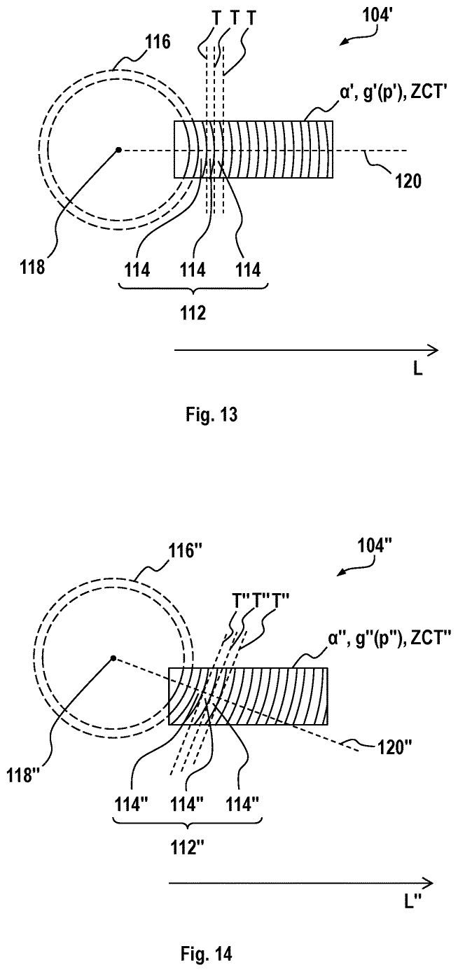

FIG. 13 shows an example of a substrate 104′ of an optical component 102 of an optical system 100 of a lithography apparatus 1, which was produced on the basis of the above-described method. The substrate 104′ comprises a distribution function g′ (p′) of a zero-crossing temperature ZCT′ of a coefficient of thermal expansion α′ as a function of a location p′ of the substrate 102′. Moreover, the distribution function g′ (p′) comprises a pattern 112 of the zero-crossing temperature ZCT′ which comprises a plurality of concentric ring sections 114, which are partial sections of a complete ring 116 in each case.

FIG. 13 shows tangents T to the ring sections 114, with the tangents T being arranged parallel to one another. Furthermore, one of the imaginary complete rings 116 of one of the ring sections 114 is indicated using dashed lines. Moreover, reference sign 118 labels an imaginary centre of the complete ring 116. FIG. 13 also plots an auxiliary line 120 (or auxiliary direction 120) of the substrate 104′. The auxiliary line 120 of the substrate 104′ is defined such that it is arranged perpendicular to the tangent T and runs through the imaginary centre 118 of the concentric complete rings 116 corresponding with the ring sections 114. In the example of FIG. 13, the auxiliary line 120 is arranged parallel to a longitudinal direction L of the substrate 104′.

The substrate 104′ shown in FIG. 13 was produced on the basis of the above-described method (i.e. cut out of the raw block 200), wherein the optimal position Pₒₚₜ of the cutout region D was selected by displacing positions Pi of the cutout region D in the radial direction r (FIG. 7) and in the height direction h (FIG. 8).

FIG. 14 shows a further example of a substrate 104″ of an optical component 102 of an optical system 100 of a lithography apparatus 1, which was produced on the basis of the above-described method. In the example of FIG. 14, the substrate 104″ was produced on the basis of a selection of the optimal position Pₒₚₜ of the cutout region D by also performing a rotation 228 about the first, second and/or third direction x′, y′, z′ of the blank 200S (FIG. 9)—in addition to the displacement of positions Pi of the cutout region D in the radial direction r and in the height direction h.

In a manner analogous to FIG. 13, it holds true for FIG. 14 that the reference sign T″ denotes tangents to ring sections 114″, with the tangents T″ being arranged parallel to one another. Furthermore, FIG. 14 also plots one of the imaginary complete rings 116″ of one of the ring sections 114″, an imaginary centre 118″ of the complete ring 116″ and an auxiliary line 120″ (or auxiliary direction 120″) of the substrate 104″. The auxiliary line 120″ of the substrate 104″ in FIG. 14 is defined just like the auxiliary line 120 in FIG. 13, specifically such that the auxiliary line 120″ is arranged perpendicular to the tangent T″ and runs through the imaginary centre 118″ of the concentric complete rings 116″ corresponding with the ring sections 114″. Unlike in the example of FIG. 13, the auxiliary line 120″ of the substrate 104″ is arranged at an angle to the longitudinal direction L″ of the substrate 104″.

Although the present invention has been described on the basis of exemplary embodiments, it can be modified in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
102 Optical component
104, 104′, 104″ Substrate
106 Optically active surface
108 Material
110 Body
112 Pattern
114, 114″ Ring section
116, 116″ Complete ring
118, 118″ Centre
120, 120″ Auxiliary line
200 Blank
202 Material
204 Body
206 Cylindrical shape
208 Surface
210 Surface
212 Surface
214 Coordinate system
216 Coordinate system
218 Pattern
220 Ring
222 Width
224 Edge
226 Edge
228 Rotation
230 Edge
232 Edge
300 Radiation
302 Image plane
304 Actual wavefront
306 Target wavefront
400 Image
402 Object
404 Object
500 Heat flux distribution
502 Heat flux pole
504 Heat flux pole
506 Optically active surface
α, α′, α″ Coefficient of thermal expansion
α_{R} Coefficient of thermal expansion
A Axis
ß Angle
B Axis
C_{q} Deviation cutout region
C₁-C₅ Deviation cutout region
D Cutout region
Dᵢ Cutout region
D₁-D₇ Cutout region
ΔFᵢ, ΔF₆ Error range
ΔF_{Fokus} Error range
Δg Error range
Δh Height range
Δr Radial range
ΔW Volume deviation
ΔZCT Temperature difference
ΔZCT_{R} Temperature difference
E_{q} Deviation aberration
E₁-E₅ Deviation aberration
F Error
Fᵢ Error
F₁-F₆ Error
fₖ Error
F₁ₛₜ first Actual focus
F_{Soll} Target focus
g, g′, g″ Function
h Height
h₁-h₅ Height
h₀, h_{A} Height
L, L″ Direction
m Total number
m₁, m₂ Centre
M Mean value
M_{R} Mean value
M1-M6 Mirrors
n Total number
p, p′, p″ Location
pⱼ Location
P₁-P₇ Position
Pₐ Selection position
Pᵢ Position
P₁-P₇ Position
Q_{q} Deviation position
Q₁-Q₅ Deviation position
r Direction
r₀, ri, rt Radius
r₁-r₅ Radius
r_{1A}, r_{1E} Radius
ρ Cylinder coordinate
φ Cylinder coordinate (angle)
S1-S5 Method steps
SW Threshold value
T, T″ Tangent
Tᵢ Tolerance region
T₁-T₃ Tolerance region
Vⱼ Volume element
W1, W2 Volume
xⱼ, yⱼ, zⱼ Location (coordinates)
x, y, z Directions
x′, y′, z′ Directions
x″, y″, z″ Directions
ZCT Zero-crossing temperature
ZCT′, ZCT″ Zero-crossing temperature
ZCTⱼ Zero-crossing temperature
ZCT_{R} Zero-crossing temperature

What is claimed is:

1. A method for producing an optical system for a lithography apparatus, the optical system comprising an optical component having a substrate cut out of a raw block, comprising:
a) providing a distribution function for a zero-crossing temperature of a coefficient of thermal expansion of the raw block as a function of a location in the raw block, the distribution function being rotationally symmetric with respect to an axis of symmetry of the raw block,
b) ascertaining, through computer implementation, an aberration of the optical system, for the provided distribution function and each of a plurality of positions of a cutout region of the raw block that differ from one another, with the plurality of positions of the cutout region differing from one another with respect to a radial position and/or a height position of the raw block, and
c) ascertaining at least one selection position of the cutout region as a selected position, selected from the plurality of positions for which the ascertained aberration is less than a predetermined threshold value.

2. The method according to claim 1, wherein an optimal position of the cutout region is ascertained in step c) as the selected position from the plurality of positions for which the ascertained aberration s minimal.

3. The method according to claim 1, wherein the cutout region is free from the axis of symmetry.

4. The method according to claim 1, wherein
the raw block has a cylindrical shape with a cylinder axis corresponding to the axis of symmetry and a lateral surface, and
the radial position of the raw block is a position along a radial direction of the raw block, with the radial direction extending from a radius equal to zero at the axis of symmetry to an outer radius at the lateral surface.

5. The method according to claim 1, wherein
the plurality of positions of the cutout region cover a radial range of the raw block from an inner radius adjacent to the axis of symmetry to an outer radius at a lateral surface of the raw block, and/or
the plurality of positions of the cutout region cover a height range of the raw block from a first end face to a second end face of the raw block.

6. The method according to claim 1, wherein
the raw block has a first, second and third direction,
the third direction is arranged along the axis of symmetry of the raw block,
the first and second direction are arranged perpendicular to one another and in each case perpendicular to the axis of symmetry, and
the plurality of positions of the cutout region differ from one another in relation to the radial position and/or the height position of the raw block and in relation to a rotation about the first, second and/or third direction.

7. The method according to claim 1, wherein
one or more deviation aberrations from one or more deviation positions of the cutout region are also ascertained for each of the plurality of positions of the cutout region that differ from one another, in addition to the aberration for the corresponding position of the corresponding cutout region,
the one or more deviation positions are chosen such that one or more deviation cutout regions defined thereby are located within a tolerance region around the corresponding cutout region defined by the corresponding position, and
the at least one selection position of the cutout region is ascertained as the position from the plurality of positions for which the ascertained aberration and the one or more ascertained deviation aberrations are each less than the predetermined threshold value.

8. The method according to claim 7, wherein
the raw block has a first, second and third direction,
the third direction is arranged along the axis of symmetry of the raw block,
the first and second direction are arranged perpendicular to one another and in each case perpendicular to the axis of symmetry, and
the one or more deviation positions differ from the corresponding position of the corresponding cutout region with respect to:
the radial position,
the height position),
a displacement in the first, second and/or third direction,
a rotation about the first, second and/or third direction,
non-parallel edges of the deviation cutout region in each case in the first, second and/or third direction, and/or
a volume deviation of the one or more deviation cutout regions from the corresponding cutout region defined by the corresponding position.

9. The method according to claim 1, wherein an error range of the ascertained aberration is additionally ascertained during the computer-implemented ascertainment of the respective aberration of the optical system, and the at least one selection position of the cutout region is ascertained as the position from the plurality of positions for which the ascertained aberration including an associated error range is less than the predetermined threshold value.

10. The method according to claim 9, wherein the respective aberration is ascertained through a computer-based simulation, and the error range of the ascertained aberration is ascertained based on one or more error ranges of one or more input parameters of the simulation.

11. The method according to claim 9, wherein the error range of the ascertained aberration is ascertained based on an error range of the provided distribution function for the zero-crossing temperature.

12. The method according to claim 9, wherein the respective aberration is ascertained through a computer-based simulation, and the error range of the ascertained aberration is ascertained with consideration to one or more systematic errors of the simulation.

13. The method according to claim 1, wherein the ascertainment of the respective aberration of the optical system includes:
ascertaining a plurality of mutually differing individual errors, in relation to mutually differing error types of the optical system, and
ascertaining the respective aberration of the optical system based on the plurality of ascertained individual errors.

14. The method according to claim 13, wherein the plurality of mutually differing individual errors are ascertained in relation to the mutually differing error types and in relation to setting parameters of an illumination of the optical component, to be produced, of the optical system with operating light that differ from one another.

15. The method according to claim 13, wherein the plurality of individual errors that differ from one another are ascertained in relation to setting parameters of a heating of the optical component, to be produced, by an external heating device that differ from one another.

16. The method according to claim 15, wherein heating of the optical component, to be produced, by the external heating device includes heating in accordance with a heating pattern or a plurality of different heating patterns, which is/are adapted accordingly for correcting one or more of the various error types, and the plurality of individual errors that differ from one another are ascertained in relation to the one heating pattern or the plurality of heating patterns that differ from one another.

17. The method according to claim 13, wherein the plurality of ascertained individual errors comprise the following in relation to the mutually differing error types:
a deviation of an actual focus of the optical system from a target focus,
a deviation of an actual position of an object imaged in an image plane of the optical system with the optical system from a target position of the imaged object,
an image displacement of an image imaged in an image plane of the optical system via the optical system, and/or
a deviation of an actual wavefront, which images an image in an image plane of the optical system, from a target wavefront.

18. The method according to claim 17, wherein
the deviation of the actual wavefront from the target wavefront comprises a tilt of the wavefront, a displacement of the wavefront, an astigmatism of the wavefront, a coma of the wavefront, a higher-order (n)-foil aberration of the wavefront and/or a spherical aberration of the wavefront, and/or
the deviation of the actual wavefront from the target wavefront is quantified through Zernike polynomials.

19. The method according to claim 1, further comprising:
providing the raw block, and
measuring the distribution function of the zero-crossing temperature of the raw block.

20. The method according to claim 1, further comprising:
providing the raw block, and
cutting out the substrate from the raw block according to the at least one ascertained selection position of the cutout region and/or an optimal position of the cutout region.
